(19) United States
(12) Patent Application Publication
(10) Pub. No.: US 2016/0090763 A1
(43) Pub. Date: Mar. 31, 2016

(54) MULTI-JOINT TURNING AXLE STRUCTURE

(71) Applicant: FIRST DOME CORPORATION, New Taipei City (TW)

(72) Inventors: AN SZU HSU, NEW TAIPEI CITY (TW); WAY HAN DAI, NEW TAIPEI CITY (TW); CHUN HAN LIN, NEW TAIPEI CITY (TW)

(21) Appl. No.: 14/569,898

(22) Filed: Dec. 15, 2014

(30) Foreign Application Priority Data
Sep. 26, 2014 (TW) 103217171

(51) Int. Cl. E05D 3/06; E05D 3/12; H05K 5/02

(52) U.S. Cl. CPC E05D 3/06; H05K 5/0226; E05D 3/122

(57) ABSTRACT

A multi-joint turning axle structure includes a driving joint assembly, a torsion joint assembly each including two opposing joint plates and at least one link unit connected therebetween. A driven joint assembly is disposed between the two opposing joint plates of one of the driving joint assembly and the torsion joint assembly, and includes two driven plates. The two driven plates have synchronous actuating portions at opposing ends thereof to form a synchronous motion. The inner ends of the joint plates of the driving joint assembly and the torsion joint assembly are respectively aligned with the outer ends of the driven plates. The outer ends of the link unit are aligned with the inner ends of the driven plates. Under a torsion function, the opposing joint plates of the driving joint assembly and the torsion joint assembly can be turned smoothly through multiple turning centers.

### BACKGROUND OF THE INVENTION

1. Field of the Invention

The present invention relates to a multi-joint turning axle structure, and more particularly to a turning axle structure which can be mounted to an electronic apparatus and provides multiple turning centers to enhance its turning freedom. Under a torsion function, the electronic apparatus can be opened or closed smoothly.

2. Description of the Prior Art

By applying a force, a pivotal axle or a turning axle mounted to an electronic apparatus (such as a cell phone, a notebook computer, a PDA, a digital camera, an electronic book, and the like) can be turned freely, such that the cover, display screen or watch window of the electronic apparatus can be turned to open or close.

In general, the electronic apparatus like a notebook computer as an example comprises a machine body module of a system end and a display module. The machine body module and the display module are connected through a pivotal device. The display module can be opened or closed relative to the machine body module with the pivotal device as the turning axis. The design of the pivotal device must consider the operation axis of the electronic apparatus and the operation angle of the display module to be opened. For example, when the display screen of the notebook is opened to 135 degrees, the pivotal device must have enough support force to position the display screen or the display module at the operation angle.

For the display module (such as screen) and/or the machine body module of the electronic apparatus to have more operation modes and to be used widely, a dual-shaft hinge disposed between the display module and the machine body module is developed, such that the display module and/or the machine body module can bring different operation modes and turning angles.

To consider the support strength and smooth operation, the aforesaid pivotal device is composed of two sets disposed at two sides of the junction of the display module and the machine body module of the electronic apparatus (such as a notebook computer). Therefore, when the display screen or the display module is turned to open, the coordination of the turning axle is not perfect. Besides, the turning freedom of the two pivotal devices disposed at the same center line is confined, so the electronic apparatus cannot be opened or closed smoothly.

To improve the aforesaid situations, a pivotal device having multiple turning centers is disclosed. A prior art comprises a driving joint assembly and a driven joint assembly. The driving joint assembly comprises two opposing joint plates and a middle link assembly disposed between the two joint plates. The two opposing joint plates have synchronous actuating portions to mesh with the middle link assembly. The driven joint assembly comprises two driven plates disposed between the two opposing joint plates of the driving joint assembly. The inner ends of the opposing joint plates are aligned with the outer ends of the driven plates and pivotally connected with axle pins. The outer end of the middle link assembly is aligned with the inner end of each driven plate and pivotally connected with an axle pin. The driving joint assembly and the driven joint assembly are arranged side by side and connected, and can be turned freely by means of multiple turning centers to form a multi-joint turning axle structure.

Typically, the aforesaid patents show the design of the turning axle and its related components. If the configuration of the turning axle and its related components can be changed to be different from the prior art, it can be used widely and enhance the convenience of operation. For example, to consider the design for the turning axle and its related components to bring a synchronous motion and to consider a convenient operation, a torsion joint mechanism is provided to enhance the stability and the positioning effect of the turning axle. The aforesaid patents do not teach or disclose that the number or torsion of the torsion joint mechanism can be changed or adjusted for the electronic apparatus to be compact and thinner according to different transmission specifications. Accordingly, the inventor of the present invention has devoted himself based on his many years of practical experiences to solve these problems.

### SUMMARY OF THE INVENTION

The primary object of the present invention is to provide a multi-joint turning axle structure to enhance its turning freedom when the turning axle structure is mounted to an electronic apparatus. Under a torsion function, the turning axle structure can be operated stably to provide a positioning effect. The multi-joint turning axle structure comprises a driving joint assembly, a driven joint assembly, and a torsion joint assembly. The driving joint assembly and the torsion joint assembly each comprise two opposing joint plates and at least one link unit connected therebetween. The driven joint assembly is disposed between the two opposing joint plates of one of the driving joint assembly and the torsion joint assembly, and includes two driven plates. The two driven plates have synchronous actuating portions at opposing ends thereof to form a synchronous motion. The inner ends of the joint plates of the driving joint assembly and the torsion joint assembly are respectively aligned with the outer ends of the driven plates and pivotally connected with axle pins. The outer ends of the link unit are aligned with the inner ends of the driven plates and pivotally connected with axle pins. Under the torsion function, the opposing joint plates of the driving joint assembly and the torsion joint assembly can be turned smoothly through multiple turning centers.

Preferably, the inner ends of the two opposing joint plates of the driving joint assembly and the torsion joint assembly are provided with synchronous actuating portions, respectively. The two ends of the link unit of the driving joint assembly and the torsion joint assembly are respectively provided with link portions corresponding to the synchronous actuating portions of the driving joint assembly and the torsion joint assembly.

Preferably, the inner ends of the two opposing joint plates of the driving joint assembly are provided with axle holes for pivotally connecting with the axle pins. The inner ends of the two opposing joint plates of the torsion joint assembly are provided with axle holes and notches communicating with the axle holes for pivotally connecting with the axle pins, such that the joint plates of the torsion joint assembly have an elastic force (torsion force) to clamp the axle pins. The two ends of the link unit of the torsion joint assembly are provided with axle holes and notches for pivotally connecting with the axle pins, such that the link unit of the torsion joint assembly has an elastic force (torsion force) to clamp the axle pins.

### BRIEF DESCRIPTION OF THE DRAWINGS

FIG. 1 is a perspective view according to a preferred embodiment of the present invention, wherein the dot-dashed lines show the display module and the machine body module coupled with the multi-joint turning axle structure;

FIG. 2 is an exploded view according to the preferred embodiment of the present invention, showing the driving joint assembly, the driven joint assembly and the torsion joint assembly;

FIG. 3 is a schematic view according to the preferred embodiment of the present invention, showing the configuration of the torsion joint assembly when the display module is closed relative to the machine body module; and

FIG. 4 is a schematic view according to the preferred embodiment of the present invention, showing the configuration of the torsion joint assembly when the display module is opened relative to the machine body module.

### DETAILED DESCRIPTION OF THE PREFERRED EMBODIMENTS

Embodiments of the present invention will now be described, by way of example only, with reference to the accompanying drawings.

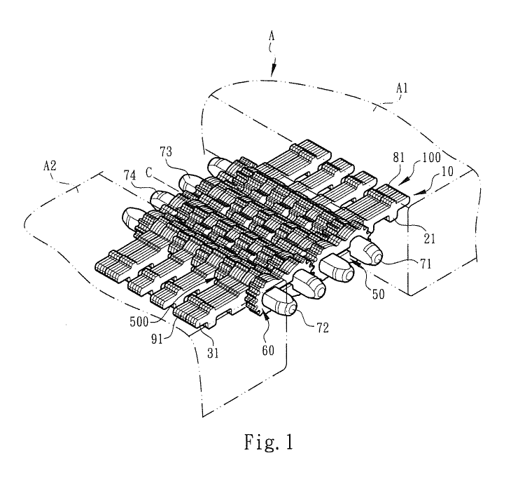

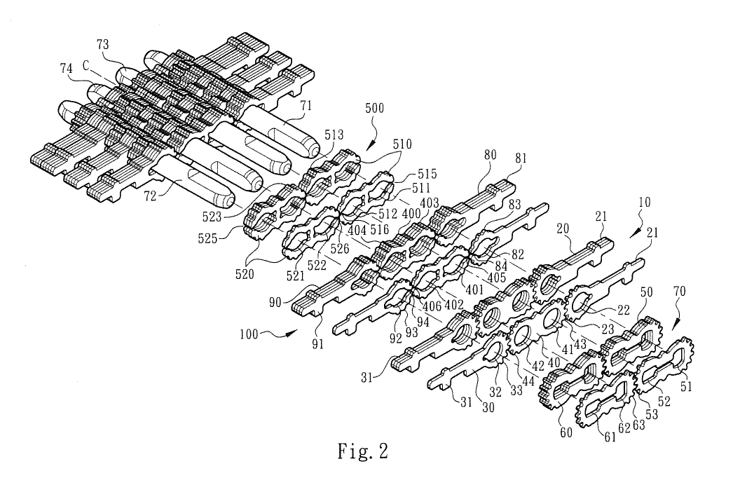

Referring to FIG. 1 and FIG. 2, the present invention discloses a multi-joint turning axle structure. The multi-joint turning axle structure comprises a driving joint assembly 10, a driven joint assembly 70, and a torsion joint assembly 100. As shown in the drawings, the driving joint assembly 10, the driven joint assembly 70, and the torsion joint assembly 100 are composed of a plurality of plates, respectively, which are arranged side by side and connected with a plurality of axle pins to form the multi-joint turning axle structure.

In order to explain the connection relationship of the elements, the central line or the baseline (datum line) C as shown in FIG. 2 is defined as a reference position for the following explanation. The direction toward the baseline C is defined as an “inward” direction. The direction away from the baseline C is defined as an “outward” direction.

As shown in FIG. 1 and FIG. 2, the driving joint assembly 10 comprises at least two opposing first and second joint plates 20, 30 and at least one link unit 40 located between the first and second joint plates 20, 30. The two opposing first and second joint plates 20, 30 have connecting ends 21, 31 at respective outer ends thereof and axle holes 22, 32 at respective inner ends thereof. At least one of the two opposing first and second joint plates 20, 30 has a synchronous actuating portion 23, 33 at the inner end thereof. As shown in the drawings, the synchronous actuating portion 23, 33 is a toothed portion formed at the outer circumferential portion of the axle hole 22, 32. The connecting ends 21, 31 of the first and second joint plates 20, 30 are connected with a display module Al and a machine body module A2 of an electronic apparatus A, respectively.

As shown in FIG. 1 and FIG. 2, the link unit 40 is disposed between the two opposing first and second joint plates 20, 30, and is composed of at least one link plate. The link unit 40 has axle holes 41, 42 and link portions 43, 44 close to two ends thereof. As shown in the drawings, the link portions 43, 44 are toothed portions formed at the outer circumferential portions of the axle holes 41, 42. The link portion 43, 44 meshes with the synchronous actuating portion 23, 33 at the inner end of the first joint plate 20 or/and the second joint plate 30, such that the first joint plate 20 or/and the second joint plate 30 and the link unit 40 can bring a synchronous motion.

In the embodiment, the driven joint assembly 70 is disposed between the first joint plate 20 and the second joint plate 30 of the driving joint assembly 10. The driven joint assembly 70 at least comprises a first driven plate 50 and a second driven plate 60. The first driven plate 50 and the second driven plate 60 have outward axle holes 51, 61 and inward axle holes 52, 62, respectively. The first driven plate 50 and the second driven plate 60 have synchronous actuating portions 53, 63 at least at respective inner ends to mesh with each other. As shown in the drawings, the synchronous actuating portions 53, 63 of the first driven plate 50 and the second driven plate 60 are toothed portions formed at the outer circumferential portions of the axle holes 52, 62.

As shown in FIG. 1 and FIG. 2, the torsion joint assembly 100 comprises at least two opposing first and second joint plates 80, 90 and at least one link unit 400 located between the first and second joint plates 80, 90. The two opposing first and second joint plates 80, 90 have connecting ends 81, 91 at respective outer ends thereof, and axle holes 82, 92 and notches 84, 94 communicating with the axle holes 82, 92 at respective inner ends thereof. At least one of the two opposing first and second joint plates 80, 90 has a synchronous actuating portion 83, 93 at the inner end thereof. As shown in the drawings, the synchronous actuating portion 83, 93 is a toothed portion formed at the outer circumferential portion of the axle hole 82, 92. The notches 84, 94 make the first joint plate 80 and the second joint plate 90 of the torsion joint assembly 100 have an elastic force (torsion force) to clamp the axle pins.

In the embodiment, the connecting ends 81, 91 of the first joint plate 80 and the second joint plate 90 of the torsion joint assembly 100 are connected with the display module Al and the machine body module A2 of the electronic apparatus A, respectively.

As shown in FIG. 1 and FIG. 2, the link unit 400 of the torsion joint assembly 100 is disposed between the two opposing first and second joint plates 80, 90, and is composed of at least one link plate. The link unit 400 has axle holes 401, 402, link portions 403, 404, and notches 405, 406 communicating with the axle holes 401, 402 close to two ends thereof. The notches 405, 406 correspond to the notches 84, 94 of the first and second joint plates 80, 90 of the torsion joint assembly 100, respectively.

As shown in the drawings, the link portions 403, 404 are toothed portions formed at the outer circumferential portions of the axle holes 401, 402. The torsion joint assembly 100 or the link portions 403, 404 of the link unit 400 mesh with the synchronous actuating portion 83, 93 at the inner end of the first joint plate 80 or/and the second joint plate 90, such that the first joint plate 80 or/and the second joint plate 90 and the link unit 400 can bring a synchronous motion.

The torsion joint assembly 100 or the notches 405, 406 make the two ends of the link unit 400 of the torsion joint assembly 100 have an elastic force (torsion force) to clamp the axle pins.

After the driving joint assembly 10, the torsion joint assembly 100, and the driven joint assembly 70 are jointed and arranged in order, the axle holes 22, 82, 32, 92 at the inner ends of the first joint plates 20, 80 and the second joint plates 30, 90 are respectively aligned with the axle holes 51, 61 at the outer ends of the first driven plate 50 and the second driven plate 60, and then pivotally connected with a first axle pin 71 and a second axle pin 72 to be assembled together. The axle holes 41, 401 42, 402 at the two ends of the link units 40, 400 of the driving joint assembly 10 and the torsion joint assembly 100 are respectively aligned with the axle holes 52, 62 at the inner ends of the first driven plate 50 and the second driven plate 60, and then pivotally connected with a third axle pin 73 and a fourth axle pin 74 to be assembled together.

Multiple driving joint assemblies 10, torsion joint assemblies 100, and driven joint assemblies 70 are arranged in order and connected with the first axle pin 71, the second axle pin 72, the third axle pin 73, and the fourth axle pin 74 to form the multi-joint turning axle structure having an elastic clamping and positioning force.

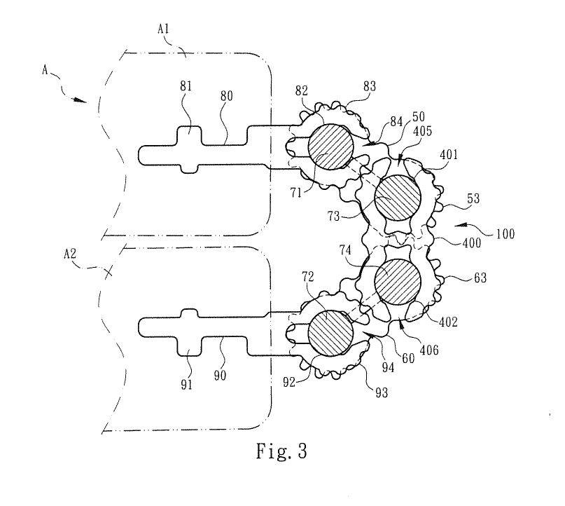

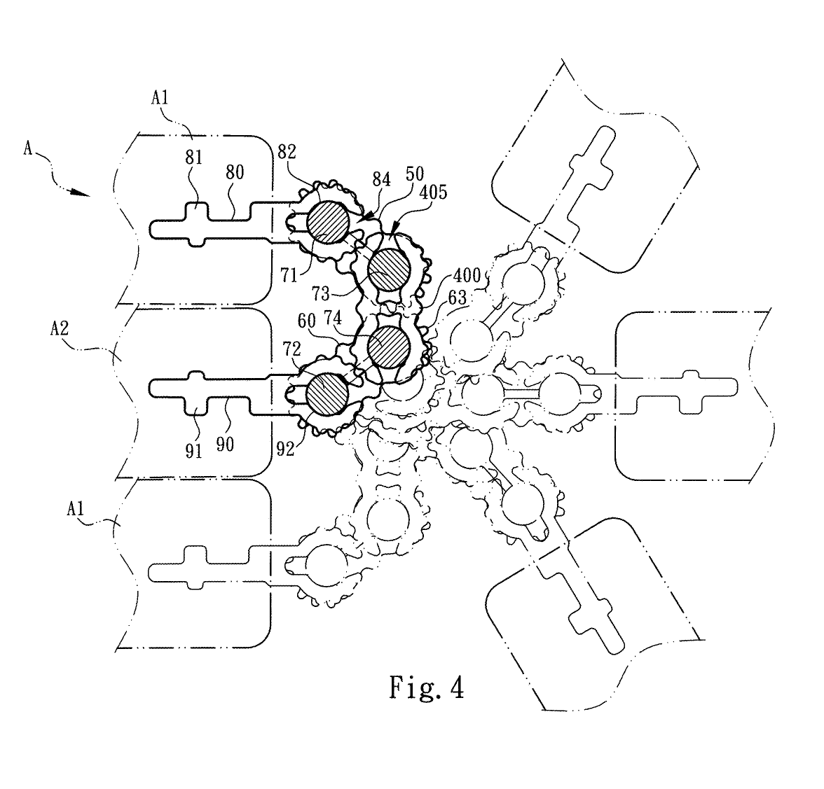

Referring to FIG. 3 and FIG. 4, when one of the joint plates (namely, the first joint plate 20, 80 or the second joint plate 30, 90) of the driving joint assembly 10 and the torsion joint assembly 100 is turned, the synchronous actuating portions 23, 83 or 33, 93 at the inner ends mesh with the link portions 43, 403 or 44, 404 at the outer ends through the middle link units 40, 400 to drive the link units 40, 400 to bring a relative reverse turning and to link the first driven plate 50 of the driven joint assembly 70 synchronously. Gradually, the entire multi-joint turning axle structure forms a synchronous turning through the torsion join assembly 100.

As shown in the drawings, when one of the joint plates (namely, the first joint plate 20, 80 or the second joint plate 30, 90) of the driving joint assembly 10 or the torsion joint assembly 100 is turned by applying a force, the other relative joint plate will be turned synchronously. That is to say, if the outer end of the first joint plate 20, 80 is turned in the clockwise direction (namely, the state shown by the solid lines of FIG. 4 is turned to the state shown by the dot-dashed lines), the inner end of the first joint plate 20, 80 will drive the outer circumference of the outer end of the link unit 40, 400 to bring a clockwise turning displacement. The outer end of the first driven plate 50 is linked to bring the same displacement, and the inner end of the first driven plate 50 is also turned clockwise. The engagement of the synchronous actuating portions 53, 63 of the first driven plate 50 and the second driven plate 60 make the inner end of the second driven plate 60 be turned synchronously in the counterclockwise direction. Therefore, the outer end of the second driven plate 60 is turned counterclockwise accordingly.

As shown in the drawings, the two opposing first joint plates 20, 80 and the second joint plates 30, 90 of the driving joint assembly 10 and the torsion joint assembly 100 uses the central line C as the datum to bring a synchronous reverse turning so as to jointly form a relative opening or closing movement. At least one joint plate is tuned toward the other relative joint plate (closing) or away from the other relative joint plate (opening), such as the state shown by the dot-dashed lines of FIG. 4.

It is noted that the two opposing joint plates (20, 30 or 80, 90) can be turned within the range of 0 degree to 360 degrees to provide a free turning. Besides, when not applied with an operation force, the torsion joint assembly 100 provides a positioning function for the electronic apparatus A.

Referring to FIG. 2, the present invention further comprises a secondary torsion joint assembly 500. The configuration of the secondary torsion joint assembly 500 can be the same as the link unit 400 of the torsion joint assembly 100, but not limited to. If the configuration of the secondary torsion joint assembly 500 is the same as the link unit 400 of the torsion joint assembly 100, it will be beneficial for the manufacture procedures.

As shown in the drawings, the secondary torsion joint assembly 500 comprises at least one or a plurality of plates composed of a first secondary torsion unit 510 and a second secondary torsion unit 520, which is disposed between the first joint plate 80 and the second joint plate 90 of the torsion joint assembly 100. The first secondary torsion unit 510 and the second secondary torsion unit 520 have separate outward axle holes 511, 521 and inward axle holes 512, 522, respectively, for pivotally connecting with the first axle pin 71, the second axle pin 72, the third axle pin 73, and the fourth axle pin 74. The first secondary torsion unit 510 and the second secondary torsion unit 520 have synchronous actuating portions 513, 523 at respective inner ends thereof to mesh with each other. As shown in the drawings, the synchronous actuating portions 513, 523 are toothed portions formed at the outer circumferential portions of the axle holes 512, 522.

In the embodiment, the first secondary torsion unit 510 and the second secondary torsion unit 520 further includes outward notches 515, 525 communicating with the outward axle holes 511, 521 and inward notches 516, 526 communicating with the inward axle holes 512, 522. The inward notch 516 of the first secondary torsion unit 510 corresponds to the inward notch 526 of the second secondary torsion unit 520. When the user operates the electronic apparatus A to turn the driving joint assembly 10 or the torsion joint assembly 100, the first secondary torsion unit 510 and the second secondary torsion unit 520 cooperate with the synchronous actuating portions 513, 523 to form a synchronous motion.

The notches 515, 525, 516, 526 of the secondary torsion joint assembly 500 make the first secondary torsion unit 510 and the second secondary torsion unit 520 each have an elastic force (torsion force) to clamp the first axle pin 71, the second axle pin 72, the third axle pin 73, and the fourth axle pin 74.

It is noted that the number or configuration of the torsion joint assembly 100 or/and the secondary torsion joint assembly 500 can be changed so as to adjust the torsion and the positioning function of the multi-joint turning axle structure.

The present invention has multiple turning centers because of the multi-joint structure. The turning freedom of the entire turning axle can be enhanced greatly. Because the two ends can be turned synchronously to be opened or closed, the turning axle can be mounted to an electronic apparatus A which can be opened and closed (such as, a foldable display, a handheld game console, a PDA, a cell phone, an electronic book, a cover for an electronic apparatus, and the like). The turning axle can be turned smoothly. The entire configuration is novel and beneficial for efficacy.

The synchronous actuating portions and the link portions are not limited to the aforesaid embodiments, which can be toothed portions, friction members, intersecting synchronous tractive members or the other equivalent members.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A multi-joint turning axle structure, comprising at least one driving joint assembly, at least one driven joint assembly, and at least one torsion joint assembly; the driving joint assembly, the driven joint assembly, and the torsion joint assembly defining a baseline, a direction toward the baseline being defined as an inward direction, a direction away from the baseline being defined as an outward direction;
the driving joint assembly comprising opposing first and second joint plates and at least one link unit connected between the first and second joint plates; at least one of the first and second joint plates having a synchronous actuating portion at an inner end thereof; at least one of two ends of the link unit having a link portion meshing with the synchronous actuating portion of the driving joint assembly;
the torsion joint assembly comprising opposing first and second joint plates and at least one link unit connected between the first and second joint plates; at least one of the first and second joint plates having a synchronous actuating portion at an inner end thereof; at least one of two ends of the link unit having a link portion meshing with the synchronous actuating portion of the torsion joint assembly;
the driven joint assembly being disposed between the inner ends of the first joint plate and the second joint plate of one of the driving joint assembly and the torsion joint assembly; the driven joint assembly comprising a first driven plate and a second driven plate; the first driven plate and the second driven plate having synchronous actuating portions at respective inner ends to mesh with each other;
the inner end of the first joint plate and the inner end of the second joint plate of the driving joint assembly and the inner end of the first joint plate and the inner end of the second joint plate of the torsion joint assembly being respectively aligned with an outer end of the first driven plate and an outer end of the second driven plate and pivotally connected with a first axle pin and a second axle pin;
the two ends of the link unit of the driving joint assembly and the two ends of the link unit of the torsion joint assembly being respectively aligned with an inner end of the first driven plate and an inner end of the second driven plate and pivotally connected with a third axle pin and a fourth axle pin.

2. The multi-joint turning axle structure as claimed in claim 1, wherein the first joint plate and the second joint plate of the driving joint assembly have connecting ends at respective outer ends thereof and axle holes at respective inner ends thereof; the two ends of the link unit of the driving joint assembly having axle holes and link portions;
the first joint plate and the second joint plate of the torsion joint assembly having connecting ends at respective outer ends thereof, and axle holes and notches communicating with the axle holes at respective inner ends thereof; the two ends of the link unit of the torsion joint assembly having axle holes, link portions, and notches communicating with the axle holes of the link unit of the torsion joint assembly;
the first driven plate and the second driven plate of the driven joint assembly having outward axle holes and inward axle holes, respectively;
the axle hole at the inner end of the first joint plate and the axle hole at the inner end of the second joint plate of the driving joint assembly and the axle hole at the inner end of the first joint plate and the axle hole at the inner end of the second joint plate of the torsion joint assembly being respectively aligned with the outward axle hole of the first driven plate and the outward axle hole of the second driven plate and pivotally connected with the first axle pin and the second axle pin;
the axle holes at the two ends of the link unit of the driving joint assembly and the axle holes at the two ends of the link unit of the torsion joint assembly being respectively aligned with the inward axle hole of the first driven plate and the inward axle hole of the second driven plate and pivotally connected with the third axle pin and the fourth axle pin.

3. The multi-joint turning axle structure as claimed in claim 1, further comprising a secondary torsion joint assembly; the secondary torsion joint assembly comprising a first secondary torsion unit and a second secondary torsion unit disposed between the first joint plate and the second joint plate of one of the driving joint assembly and the torsion joint assembly;
the first secondary torsion unit and the second secondary torsion unit having outward axle holes and inward axle holes, respectively, for pivotally connecting with the first axle pin, the second axle pin, the third axle pin, and the fourth axle pin;
the first secondary torsion unit and the second secondary torsion unit having synchronous actuating portions at respective inner ends thereof to mesh with each other so that the first secondary torsion unit and the second secondary torsion unit are linked to form a synchronous motion;
the first secondary torsion unit and the second secondary torsion unit further including outward notches communicating with the outward axle holes and inward notches communicating with the inward axle holes so that the first secondary torsion unit and the second secondary torsion unit each have an elastic clamping force; and
the inward notch of the first secondary torsion unit corresponding to the inward notch of the second secondary torsion unit.

4. The multi-joint turning axle structure as claimed in claim 2, further comprising a secondary torsion joint assembly; the secondary torsion joint assembly comprising a first secondary torsion unit and a second secondary torsion unit disposed between the first joint plate and the second joint plate of one of the driving joint assembly and the torsion joint assembly;
the first secondary torsion unit and the second secondary torsion unit having outward axle holes and inward axle holes, respectively, for pivotally connecting with the first axle pin, the second axle pin, the third axle pin, and the fourth axle pin;
the first secondary torsion unit and the second secondary torsion unit having synchronous actuating portions at respective inner ends thereof to mesh with each other so that the first secondary torsion unit and the second secondary torsion unit are linked to form a synchronous motion;
the first secondary torsion unit and the second secondary torsion unit further including outward notches communicating with the outward axle holes and inward notches communicating with the inward axle holes so that the first secondary torsion unit and the second secondary torsion unit each have an elastic clamping force; and
the inward notch of the first secondary torsion unit corresponding to the inward notch of the second secondary torsion unit.

5. The multi-joint turning axle structure as claimed in claim 2, wherein the synchronous actuating portion of the driving joint assembly is one of a toothed portion, a friction member, and an intersecting synchronous tractive member and disposed at an outer circumferential portion of a corresponding one of the axle holes of the driving joint assembly;
wherein the link portions of the link unit of the driving joint assembly are one of toothed portions, friction members, and intersecting synchronous tractive members and disposed at outer circumferential portions of the axle holes of the link unit of the driving joint assembly;
wherein the synchronous actuating portion of the torsion joint assembly is one of a toothed portion, a friction member, and an intersecting synchronous tractive member and disposed at an outer circumferential portion of a corresponding one of the axle holes of the torsion joint assembly;
wherein the link portions of the link unit of the torsion joint assembly are one of toothed portions, friction members, and intersecting synchronous tractive members and disposed at outer circumferential portions of the axle holes of the link unit of the torsion joint assembly; and
wherein the synchronous actuating portions of the first driven plate and the second driven plate of the driven joint assembly are toothed portions disposed at outer circumferential portions of the inward axle holes of the driven joint assembly.

6. The multi-joint turning axle structure as claimed in claim 3, wherein the synchronous actuating portion of the driving joint assembly is one of a toothed portion, a friction member, and an intersecting synchronous tractive member and disposed at an outer circumferential portion of a corresponding one of the axle holes of the driving joint assembly;
wherein the link portions of the link unit of the driving joint assembly are one of toothed portions, friction members, and intersecting synchronous tractive members and disposed at outer circumferential portions of the axle holes of the link unit of the driving joint assembly;
wherein the synchronous actuating portion of the torsion joint assembly is one of a toothed portion, a friction member, and an intersecting synchronous tractive member and disposed at an outer circumferential portion of a corresponding one of the axle holes of the torsion joint assembly;
wherein the link portions of the link unit of the torsion joint assembly are one of toothed portions, friction members, and intersecting synchronous tractive members and disposed at outer circumferential portions of the axle holes of the link unit of the torsion joint assembly;
wherein the synchronous actuating portions of the first driven plate and the second driven plate of the driven joint assembly are toothed portions formed at outer circumferential portions of the inward axle holes of the driven joint assembly; and
wherein the synchronous actuating portions of the first secondary torsion unit and the second secondary torsion unit are one of toothed portions, friction members, and intersecting synchronous tractive members and disposed at outer circumferential portions of the axle holes of the secondary torsion assembly.

7. The multi-joint turning axle structure as claimed in claim 4, wherein the synchronous actuating portion of the driving joint assembly is one of a toothed portion, a friction member, and an intersecting synchronous tractive member and disposed at an outer circumferential portion of a corresponding one of the axle holes of the driving joint assembly;
wherein the link portions of the link unit of the driving joint assembly are one of toothed portions, friction members, and intersecting synchronous tractive members and disposed at outer circumferential portions of the axle holes of the link unit of the driving joint assembly;
wherein the synchronous actuating portion of the torsion joint assembly is one of a toothed portion, a friction member, and an intersecting synchronous tractive member and disposed at an outer circumferential portion of a corresponding one of the axle holes of the torsion joint assembly;
wherein the link portions of the link unit of the torsion joint assembly are one of toothed portions, friction members, and intersecting synchronous tractive members and disposed at outer circumferential portions of the axle holes of the link unit of the torsion joint assembly;
wherein the synchronous actuating portions of the first driven plate and the second driven plate of the driven joint assembly are toothed portions formed at outer circumferential portions of the inward axle holes of the driven joint assembly; and
wherein the synchronous actuating portions of the first secondary torsion unit and the second secondary torsion unit are one of toothed portions, friction members, and intersecting synchronous tractive members and disposed at outer circumferential portions of the axle holes of the secondary torsion assembly.

8. The multi-joint turning axle structure as claimed in claim 1, wherein the driving joint assembly, the driven joint assembly, and the torsion joint assembly are composed of a plurality of plates, respectively.

9. The multi-joint turning axle structure as claimed in claim 2, wherein the driving joint assembly, the driven joint assembly, and the torsion joint assembly are composed of a plurality of plates, respectively.

10. The multi-joint turning axle structure as claimed in claim 3, wherein the driving joint assembly, the driven joint assembly, the torsion joint assembly, and the secondary torsion joint assembly are composed of a plurality of plates, respectively.

11. The multi-joint turning axle structure as claimed in claim 4, wherein the driving joint assembly, the driven joint assembly, the torsion joint assembly, and the secondary torsion joint assembly are composed of a plurality of plates, respectively.

12. The multi-joint turning axle structure as claimed in claim 5, wherein the driving joint assembly, the driven joint assembly, and the torsion joint assembly are composed of a plurality of plates, respectively.

13. The multi-joint turning axle structure as claimed in claim 6, wherein the driving joint assembly, the driven joint assembly, the torsion joint assembly, and the secondary torsion joint assembly are composed of a plurality of plates, respectively.

14. The multi-joint turning axle structure as claimed in claim 7, wherein the driving joint assembly, the driven joint assembly, the torsion joint assembly, and the secondary torsion joint assembly are composed of a plurality of plates, respectively.

15. The multi-joint turning axle structure as claimed in claim 2, wherein the connecting end of the first joint plate of the driving joint assembly and the connecting end of the first joint plate of the torsion joint assembly are connected to a display module of an electronic apparatus; and
the connecting end of the second joint plate of the driving joint assembly and the connecting end of the second joint plate of the torsion joint assembly are connected to a machine body module of the electronic apparatus.

16. The multi-joint turning axle structure as claimed in claim 3, wherein the connecting end of the first joint plate of the driving joint assembly and the connecting end of the first joint plate of the torsion joint assembly are connected to a display module of an electronic apparatus; and
the connecting end of the second joint plate of the driving joint assembly and the connecting end of the second joint plate of the torsion joint assembly are connected to a machine body module of the electronic apparatus.

17. The multi-joint turning axle structure as claimed in claim 4, wherein the connecting end of the first joint plate of the driving joint assembly and the connecting end of the first joint plate of the torsion joint assembly are connected to a display module of an electronic apparatus; and
the connecting end of the second joint plate of the driving joint assembly and the connecting end of the second joint plate of the torsion joint assembly are connected to a machine body module of the electronic apparatus.

18. The multi-joint turning axle structure as claimed in claim 5, wherein the connecting end of the first joint plate of the driving joint assembly and the connecting end of the first joint plate of the torsion joint assembly are connected to a display module of an electronic apparatus; and
the connecting end of the second joint plate of the driving joint assembly and the connecting end of the second joint plate of the torsion joint assembly are connected to a machine body module of the electronic apparatus.

19. The multi-joint turning axle structure as claimed in claim 6, wherein the connecting end of the first joint plate of the driving joint assembly and the connecting end of the first joint plate of the torsion joint assembly are connected to a display module of an electronic apparatus; and
the connecting end of the second joint plate of the driving joint assembly and the connecting end of the second joint plate of the torsion joint assembly are connected to a machine body module of the electronic apparatus.

20. The multi-joint turning axle structure as claimed in claim 7, wherein the connecting end of the first joint plate of the driving joint assembly and the connecting end of the first joint plate of the torsion joint assembly are connected to a display module of an electronic apparatus; and
the connecting end of the second joint plate of the driving joint assembly and the connecting end of the second joint plate of the torsion joint assembly are connected to a machine body module of the electronic apparatus.
